(19) United States
(12) Patent Application Publication
(10) Pub. No.: US 2011/0074464 A1
(43) Pub. Date: Mar. 31, 2011

(54) LOW POWER PROGRAMMABLE LOGIC DEVICES

(76) Inventors: Senani Gunaratna, Los Gatos, CA (US); Kevin Norman, Sunnyvale, CA (US); Timothy Garverick, Los Altos Hills, CA (US); Raminda Udaya Madurawe, Sunnyvale, CA (US)

(21) Appl. No.: 12/567,088

(22) Filed: Sep. 25, 2009

(51) Int. Cl. H03K 19/177

(52) U.S. Cl. 326/41

(57) ABSTRACT

Circuits and power up sequences to reduce power consumption in programmable logic devices is disclosed. A multiplexer (MUX) for a programmable logic device comprising: a plurality of inputs and an output; and a configuration circuit comprising a plurality of memory elements, each memory element generating a control signal, the configuration circuit comprising a first mode of operation to force each of said control signals to a first voltage level regardless of the memory state in the memory element; and a first device coupling a power supply voltage to the output, said first device having a gate electrode controlled by a said control signal of the configuration circuit; and one or more second devices coupling one or more inputs to the output, each said second device having a gate electrode controlled by a said control signal of the configuration circuit; wherein, the first device is in a conducting state to couple the power supply voltage to the MUX output during the first mode of operation of the configuration circuit.

### BACKGROUND

The present invention relates to low power programmable logic devices. Traditionally, integrated circuit (IC) devices such as custom, semi-custom, or application specific integrated circuit (ASIC) devices have been used in electronic products to reduce cost, enhance performance or meet space constraints. However, the design and fabrication of custom or semi-custom ICs can be time consuming and expensive. The customization involves a lengthy design cycle during the product definition phase and high Non Recurring Engineering (NRE) costs during manufacturing phase. In the event of finding a logic error in the custom or semi-custom IC during final test phase, the design and fabrication cycle has to be repeated. Such lengthy correction cycles further aggravate the time to market and engineering cost. As a result, ASICs serve only specific applications and are custom built for high volume and low cost.

Another type of semi custom device called a Gate Array customizes modular blocks at a reduced NRE cost by synthesizing the design using a software model similar to the ASIC. The missing silicon level design verification results in multiple spins and lengthy design iterations. Structured ASICs come under larger module Gate Arrays.

In recent years there has been a move away from custom or semi-custom ICs toward field programmable components whose function is determined not when the integrated circuit is fabricated, but by an end user “in the field” prior to use. Off the shelf, generic Programmable Logic Device (PLD) or Field Programmable Gate Array (FPGA) products greatly simplify the design cycle. These products offer user-friendly software to fit custom logic into the device through programmability, and the capability to tweak and optimize designs to improve silicon performance. The flexibility of this programmability is expensive in terms of silicon real estate, but reduces design cycle and upfront NRE cost to the designer.

FPGAs offer the advantages of low non-recurring engineering costs, fast turnaround (designs can be placed and routed on an FPGA in typically a few minutes), and low risk since designs can be easily amended late in the product design cycle. It is only for high volume production runs that there is a cost benefit in using the more traditional approaches. Compared to PLD and FPGA, an ASIC has hard-wired logic connections, identified during the chip design phase. ASIC has no multiple logic choices and no configuration memory to customize logic. This is a large chip area and cost saving for the ASIC. Smaller ASIC die sizes lead to better performance. A full custom ASIC also has customized logic functions which take less gate counts compared to PLD and FPGA configurations of the same functions. Thus, an ASIC is significantly smaller, faster, cheaper and more reliable than an equivalent gate-count PLD or FPGA. The trade-off is between time-to-market (PLD and FPGA advantage) versus low cost and better reliability (ASIC advantage). The cost of Silicon real estate for programmability provided by the PLD and FPGA compared to ASIC determines the extra cost the user has to bear for customer re-configurability of logic functions.

In an FPGA and PLD, a complex logic design is broken down to smaller logic blocks and shorter interconnect segments. Those elements are programmed into logic blocks and interconnect fabric provided in the FPGA. Logic elements offer sequential and combinational logic design implementations. Combinational logic has no memory and outputs reflect a function solely of present inputs. Sequential logic is implemented by inserting memory into the logic path to store past history. Existing PLD and FPGA logic elements include transistor pairs, NAND or OR type gates, multiplexers, look-up-tables (LUTs) and AND-OR type structures. In a PLD the basic logic element is labeled as macro-cell. Hereafter the terminology FPGA will include both FPGAs and PLDs, and the terminology logic element will include both logic elements and macro-cells. Granularity of a FPGA refers to logic content of a basic logic element. Smaller blocks of a complex logic design are customized to fit into FPGA grain. In fine-grain architectures, a small basic logic element is enclosed in a routing matrix and replicated. These offer easy logic fitting at the expense of complex routing. In course-grain architectures, many basic logic elements are combined with local routing and wrapped in a routing matrix to form a logic block. The logic block is then replicated with global routing. Larger logic blocks make the logic fitting difficult and the routing easier. A challenge for FPGA architectures is to provide easy logic fitting (like fine-grain) and maintain easy routing (like course-grain).

Inputs and outputs for the Logic Element or Logic Block is selected from the programmable interconnect fabric, also know as Routing Matrix. An exemplary routing matrix containing logic elements described in Ref-1 (Seals & Whapshott) is shown in FIG. 1. In that example, the inputs and outputs from Logic Element are routed to 22 horizontal and 12 vertical interconnect wires with programmable via connections. These connections may be anti-fuses or pass-gate transistors controlled by SRAM memory elements. The logic element having a built in D-flip-flop used with FIG. 1 routing as described in Ref-1 is shown in FIG. 2. In that, elements 201, 202 and 203 are 2:1 MUX's controlled by one input signal each. Element 204 is an OR gate while 205 is a D-Flip-Flop. Without global Preset & Clear signals, eight inputs feed the logic block, and one output leaves the logic block. These 9 wires are shown in FIG. 1 with programmable connectivity. All two-input, most 2-input and some 3-input variable functions are realized in the logic block and latched to the D-Flip-Flop. FPGA architectures for various commercially available devices are discussed in Ref-1 (Seals & Whapshott) as well as Ref-2 (Sharma). A comprehensive thesis on FPGA routing architecture is provides in Ref-3 (Betz, Rose & Marquardt). 3-dimensional FPGA construction is given in Ref-4 (Alexander et al.)

FPGA architectures are discussed in IDS references. Those disclose logic elements and specialized routing blocks to connect the logic elements in FPGA's. In all cases the routing block is programmed to define inputs and outputs for the logic blocks, while a logic block performs a specific logic function. Methods for implementing programmable point to point connections, synonymous with programmable switches, include fuses, antifuses, EPROM cells, EEPROM cells, Flash cells and SRAM cells. Fuse and anti-fuse are both one time programmable due to the non-reversible nature of the change. EPROM, EEPROM, Flash & SRAM incur non destructive changes. In pass-gate logic, the gate signal is generated by a configuration circuit that includes memory. The choice of memory varies from user to user. Anti-fuse and SRAM based architectures are widely used in commercial FPGA's, while EPROM, EEPROM, anti-fuse and fuse links are widely used in commercial PLD's. Volatile SRAM memory needs no high programming voltages, is freely available in every logic process, is compatible with standard CMOS SRAM memory, lends to process and voltage scaling and has become the de-facto choice for modern very large FPGA devices.

A volatile six transistor SRAM based configuration circuit is shown in FIG. 3A. The SRAM configuration memory element can be any one of 6-transistor, 5-transistor, full CMOS, R-load or TFT PMOS load based cells to name a few. Two inverters 303 and 304 connected back to back forms the memory element. This memory element is a latch. The latch can be full CMOS, R-load, PMOS load or any other. Power and ground terminals for the inverters are not shown in FIG. 3A. Access NMOS transistors 301 and 302, and access wires GA, GB, BL and BS provide the means to configure the memory element. Applying zero and one on BL and BS respectively, and raising GA and GB high enables writing zero into device 301 and one into device 302. The output S₀ delivers a logic one. Applying one and zero on BL and BS respectively, and raising GA and GB high enables writing one into device 301 and zero into device 302. The output S₀ delivers a logic zero. The SRAM construction may allow applying only a zero signal at BL or BS to write data into the latch. The SRAM cell may have only one access transistor 301 or 302. The SRAM configuration circuit in FIG. 3A controlling a logic pass-gate 310 is illustrated in FIG. 3B. Element 350 represents the configuration circuit. The S₀ output directly driven by 350 memory element drives the pass-gate 310 gate electrode. To do so, the configuration memory element and the logic node configured by the memory elements must be in close proximity. In addition to S₀ output and the latch, power, ground, data in and write enable signals in 350 constitutes the SRAM configuration circuit. Write enable circuitry includes GA, GB, BL, BS signals are shown in FIG. 3A. Logic node includes pass-gate. The SRAM latch will hold the data state as long as power is on. When the power is turned off, the SRAM bit needs to be restored to its previous state from an outside memory source. The outside memory device that stores configuration data is known as a Boot ROM. In the literature for programmable logic, the Boot ROM is sometimes labeled configuration memory, and should not be confused with the configuration memory that resides within the FPGA device. A Boot ROM comprises memory circuits that dump memory data on request over a bus to the FPGA at power-up. The request is typically made by a system CPU.

A programmable MUX utilizes a plurality of point to point switches. The 4:1 MUX in FIG. 3C operate with two configuration memory elements 361 and 362 contained in the configuration circuit 360 (not shown). One of I₀, I₁, I₂ or 1₃ is connected to O depending on the S₀ and S₁ states. For example, when S₀=1, S₁=1, I₀ is coupled to O. Similarly, when S₀=0 and S₁=0, I₃ is coupled to O.

FPGA and ASICs require buffers to improve signal propagation delay in long wires. This is shown in FIG. 4A, where the incoming signal at point A in the wire is buffered by inverter 410 and 420 in series. The two inverters are sized appropriately to drive a long segment of wire starting at B node of the wire. The buffer may drive more than one wire. A programmable bi-directional buffer from U.S. Pat. No. 4,870,302 shown in FIG. 4B has two such back-to-back buffers gated by two pass-gate logic elements 430 and 440. Unlike the full CMOS signal drive at point B in FIG. 4A, the buffers in FIG. 4B has many draw backs: (i) threshold voltage (Vt) drop in passing voltage power (Vcc) level, (ii) power consumption during power-up when input is floating, (iii) larger area for CMOS pass-gate if not to lose Vt drop, (iv) pass-gate ON resistance impacting signal delay and (v) very wide width of pass-gate (hence large area) to minimize ON resistance.

A particular difficulty with volatile configuration memory based FPGA's is the power up sequence. When a system comprising an FPGA is booted, the FPGA is not configured. Certain power up protocols must be followed to ensure proper sequencing of different circuit blocks within the FPGA. First the FPGA needs to be powered up without configuration data. Second, the FPGA must generate a signal requesting configuration data when ready to receive such data. Third, the FPGA must generate a signal that it has received the proper configuration data and its ready for operation. Without configuration data, the volatile configuration memory elements may power up at any random data state—thus all logic elements and interconnects may interact in a harmful manner. The power up time penalty and extra circuit overhead (hence cost) penalty can be considerable to avoid contentious conditions. Another undesirable effect during power up is the power consumption during power-up. The buffer structures shown in FIG. 6 have input conditions set by a proper configuration state and input state. When that is lacking, these inputs can drift to arbitrary voltage levels other that zero and Vcc. Such input states draw very large crowbar currents or steady currents through the buffers. For an FPGA device having 100K or more buffers, this current can add up to more than 100A.

A standard prior art technique to reduce power-up transient current is to add extra power control circuitry as shown in FIG. 5. FIG. 5A shows the same buffer as in FIG. 4A, with the exception of two PMOS pull-up devices 514 and 512. PMOS 514 couples input of 510 to Vcc, gated by a global signal P. The global signal P is a power-up based logic signal that is forced to a logic state “0” during power-up. The user has to ensure that P=0 until the power-up is complete, then P is set to 1 to indicate power-up is complete. During power-up, Vcc is ramped, and PMOS 514 having P=0 ensures node A is at Vcc. The output drives PMOS 512, which couples node A to Vcc by a parallel path to PMOS 514. When output of inverter 510 is driven to ground, PMOS 512 is activated to drive input A to Vcc. Both 512 and 514 are needed to ensure that node A is forced to Vcc, and then stay at Vcc to prevent inverters 510 and 520 conducting very high on currents. The problem gets worse for the bi-directional buffer shown in FIG. 4B. A required prior-art solution is shown in FIG. 5B: now there are two sets of PMOS fixes as shown in FIG. 5A. In addition to A and B nodes not having valid states, configuration outputs S₀ and S₁ also do not have valid data states. The two pull-up circuits pull both nodes A and B to Vcc level during power-up to ensure there is no crow-bar/on currents. It is easily noted that in FIG. 5B, if there are odd number of buffering stages in each leg, this solution would not work. It becomes a ring oscillator with output of one buffer feeding the input of the other buffer through on pass-gates due to undefined S₀ and S₁ values. A valid configuration is needed to shut the oscillation. During normal operation, after power up and configuration, an input transition at A from one to zero will always fight the weak pull-up 512 to consume more power per transition. It is not very convenient to distribute a global signal P throughout the chip to access every possible inverter structure to prevent crow-bar/on currents during power up, and FPGA's have over 100K such buffers.

What is desirable is to have easy to use, efficient and inexpensive power management circuits and power up conditions for FPGAs. It is also beneficial to have the ability to shut off unused power consuming devices. Such circuits should have reasonable cost parity to ASICs, easy user interface, and also lend to FPGA to ASIC easy design conversions. Many users may desire identical timing ASICs to reduce cost, save power up time and power, and at the same time not having extra time and NRE cost for design conversion to ASIC. The users further seek to avoid using an external Boot ROM as the data stream from the Boot ROM can be easily stolen during power up phase.

### SUMMARY

In one aspect, a configuration circuit for a programmable logic device comprising a plurality of memory elements and a mode to force all control signals generated by the memory elements to a zero voltage state regardless of the stored memory data.

Implementations of the above aspect may include one or more of the following. A configuration circuit comprises a memory element to generate a control signal. The control signal is coupled to a programmable element to configure the element. Most common programmable element is a pass-gate. A pass-gate is an NMOS transistor, a PMOS transistor or a CMOS transistor pair that can electrically connects two points. The gate electrode signal on these pass-gates allows a programmable method of controlling an on and off connection. Other programmable logic elements may be inverters, multiplexes and buffers. The logic device comprises circuits consisting of CMOS transistors that include AND, NAND, OR, NOR and pass-gate type logic structures. Multiple logic circuits are combined into larger logic blocks. Configuration circuits are used to change programmable logic functionality. Configuration circuits have memory elements and access circuitry to change memory data. Each memory element can be a transistor or a diode or a group of electronic devices. The memory elements can be made of CMOS devices, capacitors, diodes on a substrate. The memory elements can be made of thin film devices such as thin film transistors (TFT), capacitors and diodes. The memory element can be selected from the group consisting of volatile and non volatile memory elements. The memory element can also be selected from the group of fuses, antifuses, SRAM cells, DRAM cells, optical cells, metal optional links, EPROMs, EEPROMs, flash, magnetic and ferro-electric elements. One or more redundant memory elements can be provided for controlling the same circuit block. The memory element can generate an output signal to control logic gates. Memory element can generate a signal that is used to derive a control signal. The control signal is coupled to pass-gate logic element, AND array, NOR array, a MUX or a Look-Up-Table (LUT) logic. Configuration circuits take a large Silicon foot print, adding to cost of PLDs compared to a similar functionality ASICs. Reducing configuration circuit Silicon usage helps reduce programmable logic cost. A 3-dimensional integration of configuration circuits provides such a cost reduction. Logic circuits are fabricated using a basic logic process capable of making CMOS transistors. The pass-gates are formed on P-type, N-type, epi or SOI substrate wafers. The configuration circuits may be formed above the logic transistors. This may be achieved by inserting a thin-film transistor (TFT) module at contact layer of the logic process. The thin-film transistor outputs may be directly coupled to gate electrodes of pass-gates on substrate to provide logic control. Buried contacts may be used to make these connections. The contacts may be filled with doped poly-silicon, Titanium-Tungsten, Tungsten Silicide, or some other refractory metal. Memory elements may be constructed also with TFT transistors, capacitors and diodes. The TFT layers may be restricted for only configuration circuits, not used for logic signal lines. Metal layers above the TFT layers may be used for all the routing for the storage device, and configuration device. All signal paths may utilize wires and storage circuitry with no impact from TFT layers used for configuration circuits. This simple pass-gate switch with a vertically integrated configuration circuit reduces programmable logic cost. When the memory element is volatile, the configuration circuit has to be loaded from an external memory source called a Boot ROM. Until valid data is received the control signals have values that may be arbitrary. Such control signals may cause harmful behavior in the PLD due to contentions. A configuration circuit that guarantees a known control signal state prevents damage and reduces power consumption during power-up and configuration time.

In a second aspect, a multiplexer (MUX) for a programmable logic device, the MUX comprising: a plurality of inputs and an output; and a configuration circuit comprising a plurality of memory elements, each memory element generating a control signal, the configuration circuit comprising a first mode of operation to force each of said control signals to a first voltage level regardless of the memory state in the memory element; and a first device coupling a power supply voltage to the output, said first device having a gate electrode controlled by a said control signal of the configuration circuit; and one or more second devices coupling one or more inputs to the output, each said second device having a gate electrode controlled by a said control signal of the configuration circuit; wherein, the first device is in a conducting state to couple the power supply voltage to the MUX output during the first mode of operation of the configuration circuit.

Programmable logic devices use extensive multiplexing techniques to provide programmable choices. A plurality of wires can couple to a single wire through a MUX. The MUX is programmed by a configuration circuit. When the configuration data is missing, the MUX inputs are undefined. It is desirable to have a known input condition even when the configuration data is missing, or is incorrect. A configuration circuit that can guarantee a known zero control signal data state during a specific mode can be used to force a known condition to programmable MUX inputs. A PMOS device coupled to power-supply will conduct when the control gate is at zero volts, has the input of a MUX with a PMOS pass-gate will be forced to Vcc voltage. When the configuration circuit has this mode, the PMOS gate can either stay at zero, or programmed to one state to shut-off the PMOS. Thus a MUX structure can always posses a known data state at the input, avoiding a floating disastrous voltage level.

A buffer circuit of a programmable logic device, the circuit comprising: a buffer having a plurality of inverters coupled in series, the first inverter in the series having a buffer input; and a programmable multiplexer (MUX) comprising: a plurality of MUX inputs and a MUX output coupled to the buffer input; and a configuration circuit comprising a plurality of memory elements, each memory element generating a control signal, the configuration circuit adapted to force each of said control signals to a first voltage level regardless of the memory state in the memory element; and a first MUX device coupling a power supply voltage to the MUX output, said first device having a gate electrode controlled by a said control signal of the configuration circuit; and one or more second MUX devices coupling one or more MUX inputs to the MUX output, each said second device having a gate electrode controlled by a said control signal of the configuration circuit; wherein, the first MUX device is in a conducting state to couple the power supply voltage to the buffer input during power up and configuration of memory elements in the configuration circuit.

Implementations of the above aspect may include one or more of the following. A buffer is a circuit to amplify a signal. A simple buffer is two or three inverters in series, sized sequentially larger to generate a high drive current. Buffer output polarity can be the same or opposite of that at input. Odd and even number of stages determine the polarity. A buffer is used to transmit signals in long wires, or wires comprising a high capacitive load. A wire carries data in one direction, from a source to a sink node. A programmable wire allows the direction of data flow to be chosen by the user. A programmable buffer allows bi-directional data flow to facilitate long wire connections in programmable logic. Application specific logic also utilizes buffers to amplify signals. Buffers cause significant power surges during power up. The input conditions to buffers must be well defined. FPGA's have nondeterministic input conditions in buffers during power up and configuration. A configuration circuit with a defined mode to force control signals to zero state can aid in turning buffers off. PMOS pass-gate coupled to buffer input allows the buffer input to couple to Vcc during the special mode of configuration circuit, thus ensuring no crowbar currents in the buffer, and to prevent back-to-back bi-directional buffers entering into a ring-oscillation.

In a third aspect, a programmable logic device comprising: a configuration circuit having a plurality of memory elements, each memory element generating a control signal, the configuration circuit comprising a first mode to force all said control signals to ground voltage level; and a programmable logic circuit comprising a plurality of programmable elements, each said element coupled to one or more of said control signals; and a programmable buffer having an input coupled by a PMOS pass-gate to a power supply voltage, the gate electrode of said PMOS pass-gate coupled to a said control signal; wherein the configuration circuit is held in first mode to power up and configure the programmable logic device. In a fourth aspect, a power up sequence of a programmable logic device comprises forcing a configuration circuit into a mode wherein all control signals generated by memory elements in the circuit are forced to zero voltage until the configuration circuit is configured.

Implementations of the above aspect may further include one or more of the following. The memory element can be selected from the group of volatile or non-volatile memory elements. Volatile memory needs to be loaded at power up. The memory can be implemented using a TFT process technology that contains one or more of Fuses, Anti-fuses, DRAM, EPROM, EEPROM, Flash, Ferro-Electric, optical, magnetic and SRAM elements. Configuration circuits may include thin film elements such as diodes, transistors, resistors and capacitor. The process implementation is possible with any memory technology where the programmable element is vertically integrated in a removable module. The configuration circuit includes a predetermined conductive pattern in lieu of memory elements to control the programmable logic in the storage circuits. Multiple memory bits exist to customize logic functions. Each memory bit pattern has a corresponding unique conductive pattern to duplicate the same customized logic function. Circuit performance of the logic function is not affected by the choice of logic control: memory elements or conductive pattern. Forcing control signals to zero state regardless of memory values allow the logic circuits to power up in known states to prevent logic contention and high power consumption.

Implementations of the above aspects may include one or more of the following. The novel circuits and power up sequence constitutes fabricating a power managed VLSI IC product. The IC product is re-programmable in its initial stage with turnkey conversion to an ASIC. The IC has the end ASIC cost structure and FPGA re-programmability with superior power management. The IC product offering occurs in two phases: the first stage is a generic FPGA that has re-programmability containing a programmable module, and the second stage is an ASIC with the entire programmable module replaced by a customized metal mask.

A series product families can be provided with a modularized programmable element in an FPGA version followed by a turnkey custom ASIC with the same base die with 1-2 custom masks. The vertically integrated programmable module does not consume valuable silicon real estate of a base die. Furthermore, the design and layout of these product families adhere to removable module concept: ensuring the functionality and timing of the product in its FPGA and ASIC canonicals. These IC products can replace existing PLD and FPGA products and compete with existing Gate Arrays and ASIC's in cost and performance. An easy turnkey customization of an ASIC from an original smaller cheaper and faster PLD or FPGA would greatly enhance time to market, performance, and product reliability.

### BRIEF DESCRIPTION OF THE DRAWINGS

FIG. 1 shows an exemplary interconnect structure utilizing a logic element.

FIG. 2 shows an exemplary logic element.

FIG. 3A shows an exemplary configuration circuit for a 6T SRAM element.

FIG. 3B shows an exemplary programmable pass-gate switch with SRAM memory.

FIG. 3C shows an exemplary 4:1 MUX controlled by 2 SRAM bits.

FIG. 4A shows an exemplary CMOS buffer comprising two inverters.

FIG. 4B shows an exemplary programmable bi-directional buffer.

FIG. 5A shows an exemplary CMOS buffer to reduce crowbar current during power-up.

FIG. 5B shows an exemplary programmable bi-directional buffer to reduce crowbar current during power-up.

FIG. 6A shows related art of a first special configuration circuit.

FIG. 6B shows related art of a second special configuration circuit.

FIG. 7A shows a novel multiplexer and buffer structure.

FIG. 7B shows a novel multiplexer and bi-directional buffer structure.

FIG. 8 shows a 3-dimensional construction of a programmable device.

FIG. 9 shows constructional process cross sections of a TFT process.

FIG. 10 shows a 1^{st} embodiment of a novel programmable logic device.

FIG. 11 shows a 2^{st} embodiment of a novel programmable logic device.

FIG. 12 shows a 3^{rd} embodiment of a novel programmable logic device.

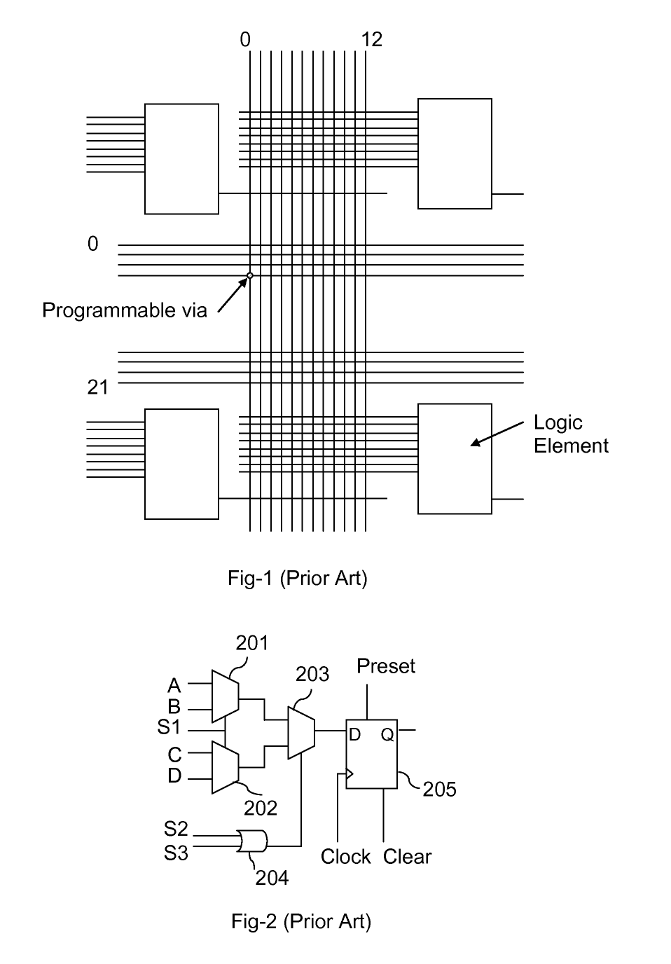

### DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention.

Definitions: The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, SOI material as well as other semiconductor structures well known to one skilled in the art. The term conductor is understood to include semiconductors, and the term insulator is defined to include any material that is less electrically conductive than the materials referred to as conductors.

The term module layer includes a structure that is fabricated using a series of predetermined process steps. Wafer processing includes masking layers, deposition and etching techniques. The boundary of the structure is defined by a first step, one or more intermediate steps, and a final step. The resulting structure is formed on a substrate. A cross section of the fully fabricated device may be used to delineate the module layers.

The term pass-gate refers to a structure that can pass a signal when on, and blocks signal passage when off. A pass-gate connects two points when on, and disconnects two points when off. A pass-gate can be a floating-gate transistor, an NMOS transistor, a PMOS transistor or a CMOS transistor pair. The gate electrode of pass-gate determines the state of the connection. A CMOS pass-gate requires complementary signals coupled to NMOS and PMOS gate electrodes. A control logic signal is connected to gate electrode of a pass-gate for programmable logic.

The term configuration circuit includes one or more configurable elements and connections that can be programmed for controlling one or more circuit blocks in accordance with a predetermined user-desired functionality. The configuration circuit includes the memory element and the access circuitry, herewith called memory circuitry (memory circuits include decoders, word lines, bit lines and sensing devices required to access individual memory bits arranged in an array) to modify said memory element. In configuration circuits, each memory element generates a control signal that is coupled to a programmable circuit to program the programmable circuit. In a typical memory circuit of a memory device, as all memory elements are coupled together, no individual memory element generates a control signal. Configuration circuit does not include the logic pass-gate controlled by the memory element. In one embodiment, the configuration circuit includes a plurality of memory circuits to store instructions to configure an FPGA. In another embodiment, the configuration circuit includes a first selectable configuration where a plurality of memory circuits is formed to store instructions to control one or more circuit blocks. The configuration circuits include a second selectable configuration with a predetermined conductive pattern formed in lieu of the memory circuit to control substantially the same circuit blocks. The configuration circuit includes elements such as diode, transistor, resistor, capacitor, metal link, among others. The configuration circuit also includes thin film elements. In yet another embodiment, the configuration circuits include a predetermined conductive pattern, via, resistor, capacitor or other suitable circuits formed in lieu of the memory circuit to control substantially the same circuit blocks.

The term “horizontal” as used in this application is defined as a plane parallel to the conventional plane or surface of a wafer or substrate, regardless of the orientation of the wafer or substrate. The term “vertical” refers to a direction perpendicular to the horizontal direction as defined above. Prepositions, such as “on”, “side”, “higher”, “lower”, “over” and “under” are defined with respect to the conventional plane or surface being on the top surface of the wafer or substrate, regardless of the orientation of the wafer or substrate. The following detailed description is, therefore, not to be taken in a limiting sense.

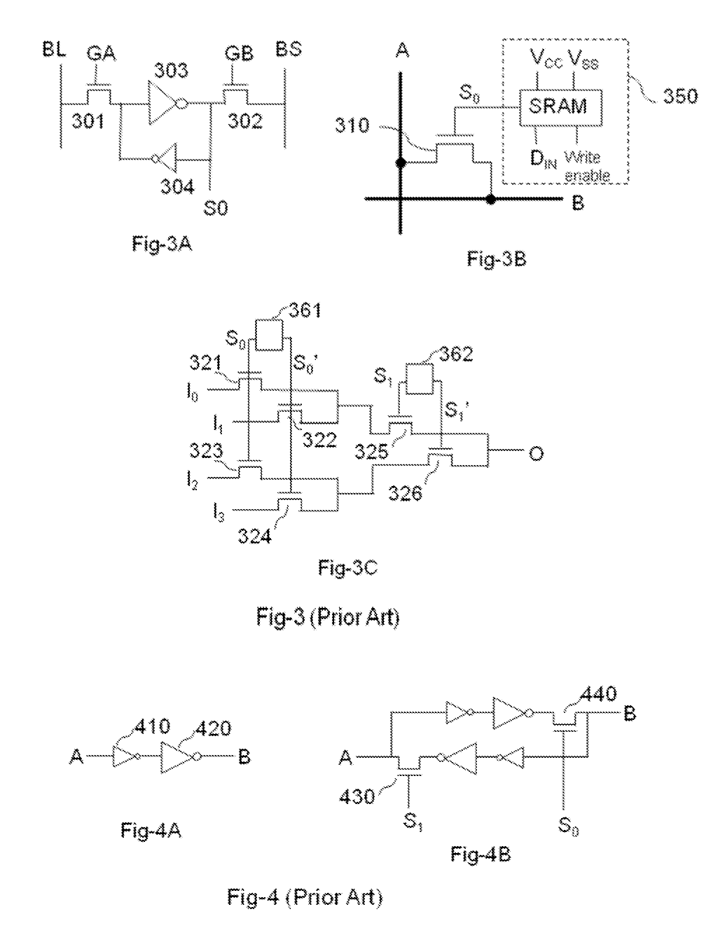

A significant draw back with the SRAM configuration circuit in FIG. 3A is the unknown state of control signal S₀ during power up. Inverters 303 and 304 are coupled to Vcc that is ramped up from ground voltage. Each SRAM bit will capture a random data point based random processing related variations and voltage coupling conditions. Configuration circuits that can resolve these problems was disclosed in application Ser. No. 11/986,025, filed Nov. 19, 2007, which lists as inventor Mr. Madurawe, the contents of which are incorporated by reference. The related art is shown in FIGS. 6A & 6B.

FIG. 6A shows an SRAM cell based configuration circuit that can be used with the present invention. It is similar to FIG. 3A, with the exception of added buffer 605 that isolates the SRAM latch portion from the control signal S₀. The control signal is a derived signal based on the SRAM storage state. The latch comprising inverter pair 603, 604 is power by a first power supply Vc. The buffer 604 is powered by a second power supply Vp. During Vc ramp (ie power up), Vp=0 will ensure S₀ signal being either at Vs or within a PMOS threshold voltage of Vs. Once the Vc is fully ramped, any logic circuit within the FPGA can generate a signal requesting configuration data from the Boot ROM. All SRAM bits in FIG. 6A can be loaded still holding Vp=0. When the configuration is fully completed, Vp can be ramped to Vc to activate the appropriate signal levels on the control signals. Such a circuit will maintain S₀=0 and S₁=0 (within a PMOS Vt level) of FIG. 4B during power up.

FIG. 6B shows a second embodiment of a configuration circuit that can be used with the current invention. Again the traditional SRAM based circuit of FIG. 3A is modified to generate a derived signal based on stored data in the latch. Either two NMOS transistors 615 and 616 (as shown) or two PMOS transistors (not shown) may be used to construct a voltage converter circuit. The latch 613/614 is powered by a first power supply VC, while the voltage converter is powered by a second power supply Vp. Similar to FIG. 6A, while Vc is ramping, holding Vp=0 will ensure S₀=0 regardless of data state within SRAM. When Vp=Vs=0, since one of two NMOS devices 615 or 616 will always be on regardless of latch state, S₀=0 is guaranteed. Such a circuit will also maintain S₀=0 and S₁=0 in FIG. 4B during power up.

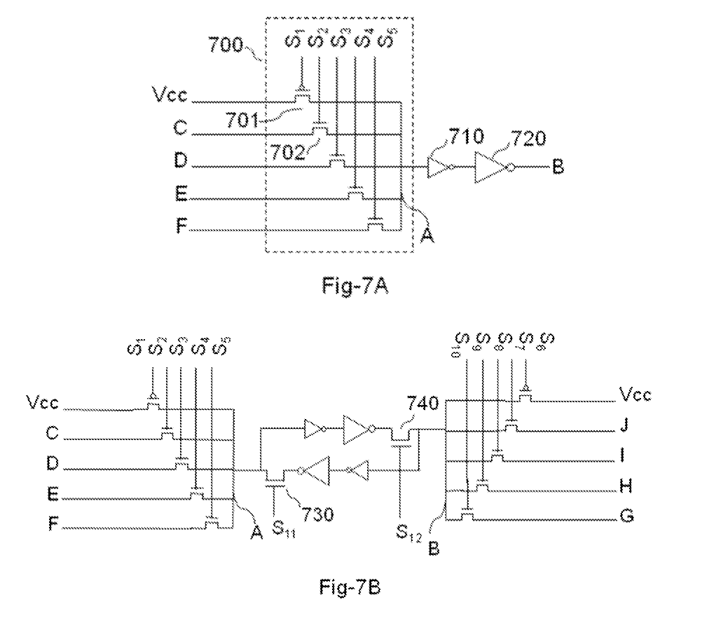

FIG. 7A shows a first embodiment of a crowbar current control circuit during power up for an FPGA. FIG. 7A is a simple buffer structure that has a 700 MUXd input A and buffered output B. The 700 MUXd input A is selected from a plurality of inputs C-F. A plurality of configuration bits S₂ through S₅ determines which of the MUX inputs is coupled to A. Each coupling is accomplished by a similar NMOS 701 pass-gate logic element, similar to that shown in FIG. 3B. However, unlike the prior work, two new features are added to the buffer input A to control crowbar currents in the buffer structure during power-up, and to shut down the buffer structure if it is not in use. The first is the addition of a PMOS 701 pass-gate configured by a configuration bit S₁. The second is that each control signal is generated by a configuration circuit as shown in FIG. 6. That is, the control signal is a derived signal from a volatile storage element. While the storage element is configured, the derived signal can be maintained at ground voltage regardless of the storage element stored value. (In other embodiments the ground voltage of voltage converter circuit may be ramped together with V_{P} to a preferred voltage level). During power-up, all configuration bit values are driven to zero. The power supply Vcc may or may not be same as the power supply voltage for the storage element. However, Vcc is the logic core voltage that is required to power up all logic signals within the FPGA. As Vcc ramps up, S₁=0 signal drives the PMOS 701 coupling to force A node at the input to inverter 710 to zero. Thus the inverter pair has a forced voltage at the input, thus preventing crowbar current. It is easily seen that once the configuration is completed, any one of C through F may couple to A, thus forcing the input to a valid logic state. In such an event, setting S₁=1 is used to turn the PMOS 701 coupling to Vcc off. If A is an unused input, then setting S₁=0 is used to turn the PMOS coupling to Vcc on to prevent a tri-state floating condition at input A. Inspecting prior art shown in FIG. 4A, it is seen that there is no easy solution to prevent node A having a floating voltage when no output is connected to it. In such cases, in prior-art, users may be forced to generate additional logic (not specified in the design) to artificially generate a fixed voltage to node A (through inputs C-F) and program the MUX to make that connection; a wastage of additional logic and routing resources at extra cost. All NMOS 702 gates controlled by zero settings of configuration bit outputs decouple inputs C-F from coupling to node A.

FIG. 7A shows a multiplexer (MUX) 700 for a programmable logic device, the MUX comprising: a plurality of inputs (Vcc, C-F) and an output A; and a configuration circuit (such as in FIG. 6B) comprising a plurality of memory elements (such as latch 613/614 in FIG. 6B), each memory element generating a control signal (S₁-S₅), the configuration circuit comprising a first mode of operation to force each of said control signals to a first voltage level regardless of the memory state in the memory element (such as setting V_{P}=0 in FIG. 6B); and a first device 701 coupling a power supply voltage Vcc to the output, said first device having a gate electrode controlled by a said control signal S₁ of the configuration circuit; and one or more second devices 702 coupling one or more inputs to the output, each said second device having a gate electrode controlled by a said control signal S₂ of the configuration circuit; wherein, the first device is in a conducting state to couple the power supply voltage to the MUX output during the first mode of operation of the configuration circuit.

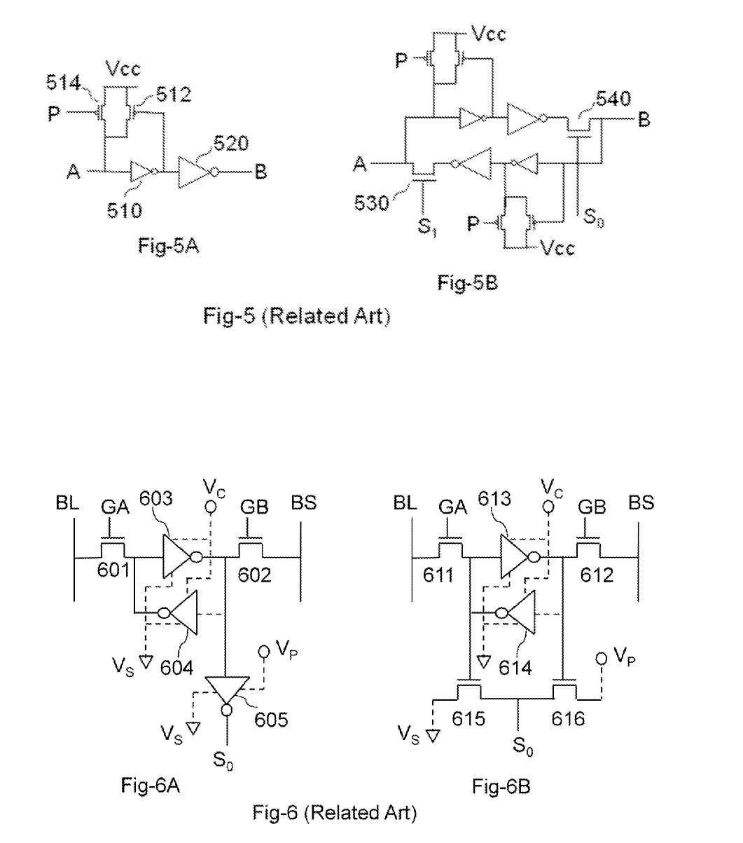

In FIG. 7B, a bi-directional buffer according to current teaching is shown. A first plurality of inputs/outputs C-F is coupled to a second plurality of inputs/outputs G-J through the prior-art bi-directional buffer shown in FIG. 4B. In FIG. 4B and 5B, S₀ and S₁ signals powered up at undefined states, meaning they could be on states or off states or in-between states. With odd stages in the buffer, this causes back-to-back buffer coupling through leaky (or on) switches that generates a ring oscillator. The ring-oscillator consumes dynamic power. The pull-up circuit in FIG. 5B is too weak to prevent the voltage oscillation. With the configuration circuit in FIG. 6, the signals S₁₁ and S₁₂ in FIG. 7B can be ensured to be at zero (or close to zero). Thus in FIG. 7B, the buffer can have even or odd number of stages without forming a power consuming ring-oscillator during power-up. It is easily seen that all the control signals S₁-S₁₂ are forced to zero (or near zero) by the configuration circuit during power up as V_{P} (in FIG. 6) is held at ground voltage. Thus the NMOS pass-gates are off. However, S₁ signal on PMOS gate drives node A to the ramping Vcc voltage, and S₆ signal on PMOS gate drives node B to the ramping Vcc voltage, ensuring no crow-bar currents in both the buffer structures.

A new kind of a programmable logic device utilizing thin-film transistor configurable circuits is disclosed in application Ser. No. 10/267,483 entitled “Three Dimensional Integrated Circuits”, application Ser. No. 10/267,484 entitled “Methods for Fabricating Three-Dimensional Integrated Circuits”, and U.S. Pat. No. 6,747,478 and list as inventor Mr. R. U. Madurawe, the contents of which are incorporated-by-reference. The disclosures describe a programmable logic device and an application specific device fabrication from the same base Silicon die. The PLD is fabricated with a programmable memory module, while the ASIC is fabricated with a conductive pattern in lieu of the memory. Both memory module and conductive pattern provide identical control of logic circuits. For each set of memory bit patterns, there is a unique conductive pattern to achieve the same logic functionality. The vertical integration of the configuration circuit leads to a significant cost reduction for the PLD, and the elimination of TFT memory for the ASIC allows an additional cost reduction for the user. The TFT vertical memory integration scheme is briefly described next.

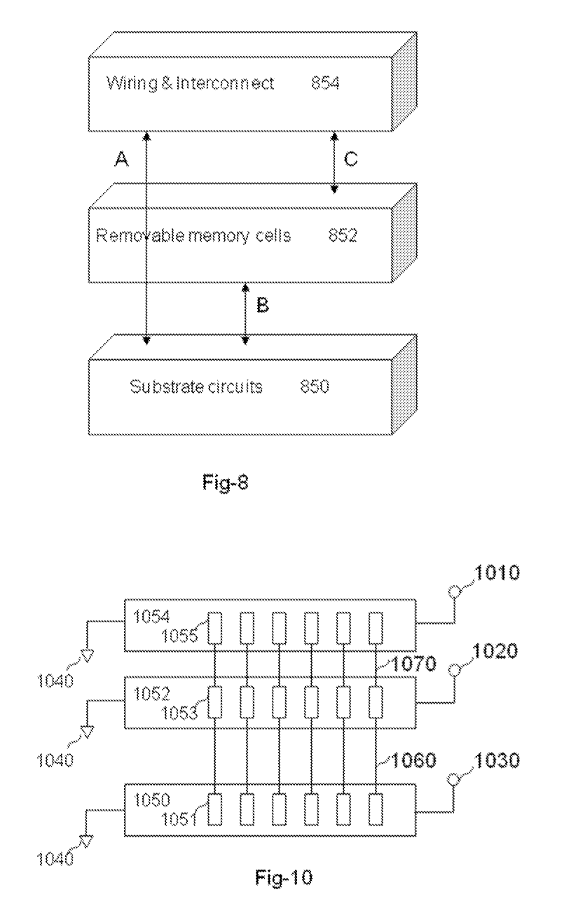

FIG. 8 shows an implementation of vertically integrated circuits, where the configuration memory element is located above logic. The memory element can be any one of fuse links, anti-fuse capacitors, SRAM cells, DRAM cells, metal optional links, EPROM cells, EEPROM cells, flash cells, ferro-electric elements, optical elements and magnetic elements that lend to this implementation. SRAM memory is used herein to illustrate the scheme and is not to be taken in a limiting sense. First, silicon transistors 850 are deposited on a substrate. A module layer of removable SRAM cells 852 are positioned above the silicon transistors 850, and a module layer of interconnect wiring or routing circuit 854 is formed above the removable memory cells 852. To allow this replacement, the design adheres to a hierarchical layout structure. As shown in FIG. 8, the SRAM cell module is sandwiched between the single crystal device layers below and the metal layers above electrically connecting to both. It also provides through connections “A” for the lower device layers to upper metal layers. The SRAM module contains no switching electrical signal routing inside the module. All such routing is in the layers above and below. Most of the programmable element configuration signals run inside the module. Upper layer connections to SRAM module “C” are minimized to Power, Ground and high drive data wires. Connections “B” between SRAM module and single crystal module only contain logic level signals and replaced later by Vcc and Vss wires. Most of the replaceable programmable elements and its configuration wiring is in the “replaceable module” while all the devices and wiring for the end ASIC is outside the “replaceable module”. In other embodiments, the replaceable module could exist between two metal layers or as the top most module layer satisfying the same device and routing constraints. This description is equally applicable to any other configuration memory element, and not limited to SRAM cells.

Fabrication of the IC also follows a modularized device formation. Formation of transistors 850 and routing 854 is by utilizing a standard logic process flow used in the ASIC fabrication. Extra processing steps used for memory element 852 formation are inserted into the logic flow after circuit layer 850 is constructed. A full disclosure of the vertical integration of the TFT module using extra masks and extra processing is in the incorporated by reference applications discussed above.

During the customization, the base die and the data in those remaining mask layers do not change making the logistics associated with chip manufacture simple. Removal of the SRAM module provides a low cost standard logic process for the final ASIC construction with the added benefit of a smaller die size. The design timing is unaffected by this migration as lateral metal routing and silicon transistors are untouched. Software verification and the original FPGA design methodology provide a guaranteed final ASIC solution to the user. A full disclosure of the ASIC migration from the original FPGA is in the incorporated by reference applications discussed above.

In FIG. 8, the third module layer is formed substantially above the first and second module layers, wherein interconnect and routing signals are formed to connect the circuit blocks within the first and second module layers. Alternatively, the third module layer can be formed substantially below the first and second module layer with interconnect and routing signals formed to connect the circuit blocks within the first and second module layers. Alternatively, the third and fourth module layers positioned above and below the second module layer respectively, wherein the third and fourth module layers provide interconnect and routing signals to connect the circuit blocks within the first and second module layers.

In yet another embodiment of a programmable multi-dimensional semiconductor device, a first module layer is fabricated having a plurality of circuit blocks formed on a first plane. The programmable multi-dimensional semiconductor device also includes a second module layer formed on a second plane. A plurality of configuration circuits is then formed in the second plane to store instructions to control a portion of the circuit blocks.

The fabrication of thin-film transistors to construct configuration circuits is discussed next. A full disclosure is provided in application Ser. No. 10/413,809 entitled “Semiconductor Switching Devices”, filed on Apr. 14, 2003, which lists as inventor Mr. R. U. Madurawe, the contents of which are incorporated herein by reference.

The following terms used herein are acronyms associated with certain manufacturing processes. The acronyms and their abbreviations are as follows:

V_{T} Threshold voltage

LDN Lightly doped NMOS drain

LDP Lightly doped PMOS drain

LDD Lightly doped drain

RTA Rapid thermal annealing

Ni Nickel

Ti Titanium

TiN Titanium-Nitride

W Tungsten

S Source

D Drain

G Gate

ILD Inter layer dielectric

C1 Contact-1

M1 Metal-1

P1 Poly-1

P− Positive light dopant (Boron species, BF₂)

N− Negative light dopant (Phosphorous, Arsenic)

P+ Positive high dopant (Boron species, BF₂)

N+ Negative high dopant (Phosphorous, Arsenic)

Gox Gate oxide

C2 Contact-2

LPCVD Low pressure chemical vapor deposition

CVD Chemical vapor deposition

ONO Oxide-nitride-oxide

LTO Low temperature oxide

A logic process is used to fabricate CMOS devices on a substrate layer for the fabrication of storage circuits. These CMOS devices may be used to build AND gates, OR gates, inverters, adders, multipliers, memory and pass-gate based logic functions in an integrated circuit. A CMOSFET TFT module layer or a Complementary gated FET (CGated-FET) TFT module layer may be inserted to a logic process at a first contact mask to build a second set of TFT MOSFET or Gated-FET devices. Configuration circuitry is build with these second set of transistors. An exemplary logic process may include one or more following steps:

P-type substrate starting wafer

Shallow Trench isolation: Trench Etch, Trench Fill and CMP

Sacrificial oxide

PMOS V_{T} mask & implant

NMOS V_{T} mask & implant

Pwell implant mask and implant through field

Nwell implant mask and implant through field

Dopant activation and anneal

Sacrificial oxide etch

Gate oxidation/Dual gate oxide option

Gate poly (GP) deposition

GP mask & etch

LDN mask & implant

LDP mask & implant

Spacer oxide deposition & spacer etch

N+ mask and NMOS N+ G, S, D implant

P+ mask and PMOS P+ G, S, D implant

Ni deposition

RTA anneal—Ni salicidation (S/D/G regions & interconnect)

Unreacted Ni etch

ILD oxide deposition & CMP

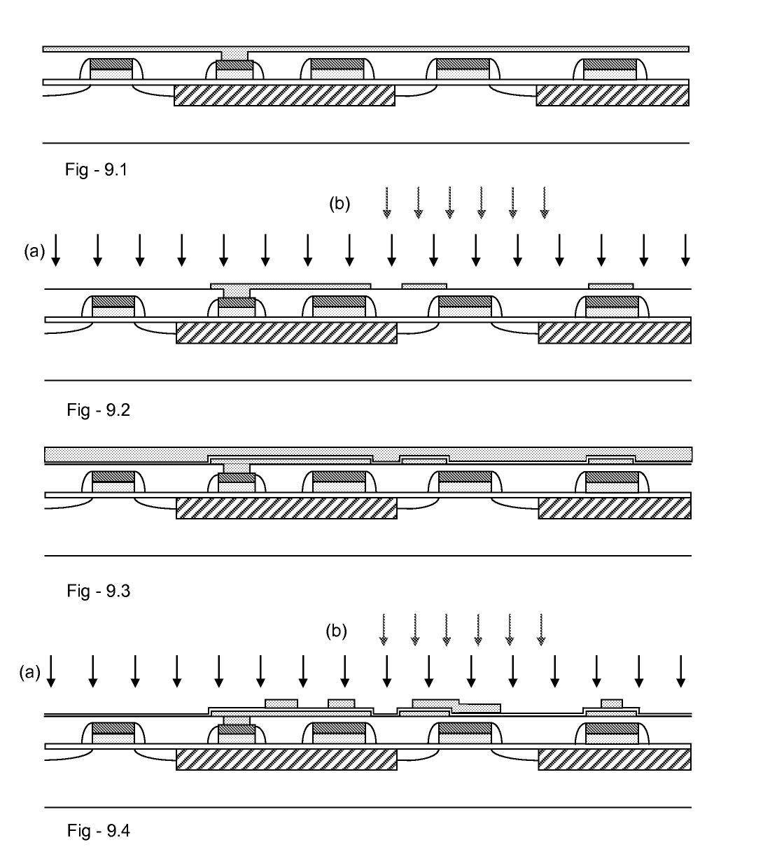

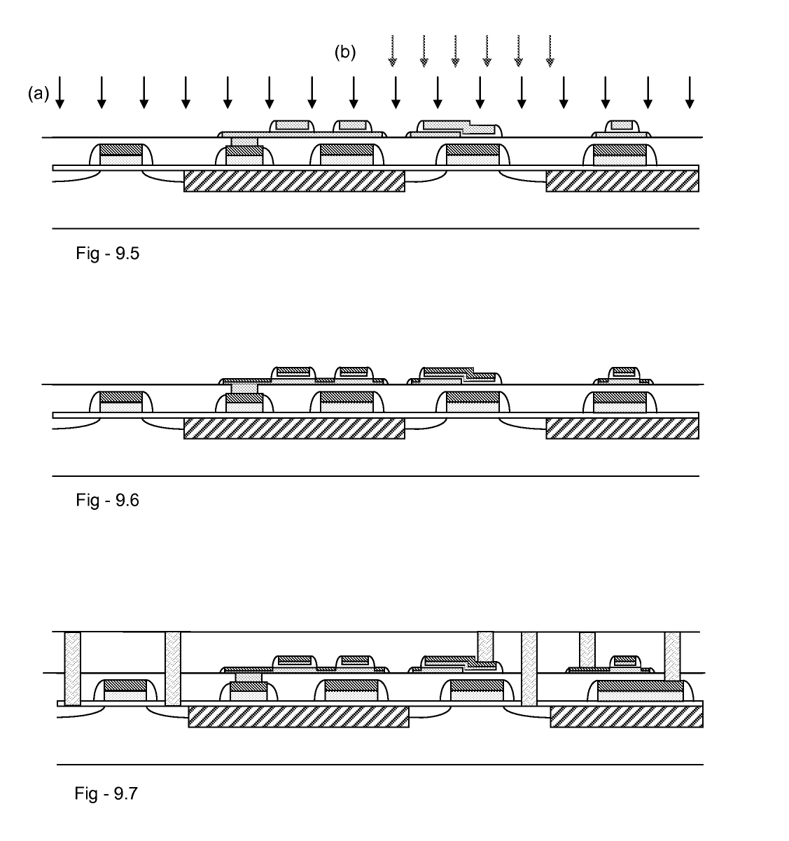

FIG. 9 shows an exemplary process for fabricating a thin film MOSFET latch in a module layer. In one embodiment the process in FIG. 9 forms the latch in a layer substantially above the substrate layer. The processing sequence in FIG. 9.1 through 9.7 describes the physical construction of a MOSFET device for storage circuits 350 shown in FIG. 3B. The process of FIG. 9 includes adding one or more following steps to the logic process after ILD oxide CMP step.

C1 mask & etch

W-Silicide plug fill & CMP

200A to 500A poly P1 (amorphous poly-1) deposition

P1 mask & etch

Vtn mask & P− implant (NMOS Vt)

Vtp mask & N− implant (PMOS Vt)

TFT Gox (70A PECVD) deposition

200A to 500A P2 (amorphous poly-2) deposition

P2 mask & etch

LDN mask and NMOS N− tip implant

LDP mask and PMOS P− tip implant

Spacer LTO deposition

Spacer LTO etch to form spacers & expose P1

N+ mask implant (NMOS G/S/D & interconnect)

P+ mask & implant (PMOS G/S/D & interconnect)

Ni deposition

RTA salicidation and poly re-crystallization (G/S/D regions & interconnect)

Dopant activation anneal

Excess Ni etch

ILD oxide deposition & CMP

C2 mask & etch

W plug formation & CMP

M1 deposition and back end metallization

The TFT process technology consists of creating NMOS & PMOS poly-silicon transistors. In the embodiment in FIG. 9, the module insertion is after the substrate device gate poly etch and the ILD film is deposition. In other embodiments the insertion point may be after M1 and the ILD is deposition, prior to V1 mask, or between two metal definition steps.

After gate poly of regular transistors are patterned and etched, the poly is salicided using Nickel & RTA sequences. Then the ILD is deposited, and polished by CMP techniques to a desired thickness. In the shown embodiment, the contact mask is split into two levels. The first C1 mask contains all contacts that connect latch outputs to substrate transistor gates and active nodes. Then the C1 mask is used to open and etch contacts in the ILD film. Ti/TiN glue layer followed by W-Six plugs, W plugs or Si plugs may be used to fill the plugs, then CMP polished to leave the fill material only in the contact holes. The choice of fill material is based on the thermal requirements of the TFT module.

Then, a first P1 poly layer, amorphous or crystalline, is deposited by LPCVD to a desired thickness as shown in FIG. 9.1. The P1 thickness is between 50A and 800A, and preferably 250A. This poly layer P1 is used for the channel, source, and drain regions for both NMOS and PMOS TFT's. It is patterned and etched to form the transistor body regions. In other embodiments, P1 is used for contact pedestals. NMOS transistors are blanket implanted with P− doping, while the PMOS transistor regions are mask selected and implanted with N− doping. This is shown in FIG. 9.2. The implant doses and P1 thickness are optimized to get the required threshold voltages for PMOS & NMOS devices under fully depleted transistor operation, and maximize on/off device current ratio. The pedestals implant type is irrelevant at this point. In another embodiment, the V_{T} implantation is done with a mask P− implant followed by masked N− implant. First doping can also be done in-situ during poly deposition or by blanket implant after poly is deposited.

Patterned and implanted P1 may be subjected to dopant activation and crystallization. In one embodiment, RTA cycle is used to activate & crystallize the poly after it is patterned to near single crystal form. In a second embodiment, the gate dielectric is deposited, and buried contact mask is used to etch areas where P1 contacts P2 layer. Then, Ni is deposited and salicided with RTA cycle. All of the P1 in contact with Ni is salicided, while the rest poly is crystallized to near single crystal form. Then the unreacted Ni is etched away. In a third embodiment, amorphous poly is crystallized prior to P1 patterning with an oxide cap, metal seed mask, Ni deposition and MILC (Metal-Induced-Lateral-Crystallization).

Then the TFT gate dielectric layer is deposited followed by P2 layer deposition. The dielectric is deposited by PECVD techniques to a desired thickness in the 30-200A range, desirably 70A thick. The gate may be grown thermally by using RTA. This gate material could be an oxide, nitride, oxynitride, ONO structure, or any other dielectric material combination used as gate dielectric. The dielectric thickness is determined by the voltage level of the process. At this point an optional buried contact mask (BC) may be used to open selected P1 contact regions, etch the dielectric and expose P1 layer. BC could be used on P1 pedestals to form P1/P2 stacks over C1. In the P1 salicided embodiment using Ni, the dielectric deposition and buried contact etch occur before the crystallization. In the preferred embodiment, no BC is used.

Then second poly P2 layer, 200A to 2000A thick, preferably 300A is deposited as amorphous or crystalline poly-silicon by LPCVD as shown in FIG. 9.3. P2 layer is defined into NMOS & PMOS gate regions intersecting the P1 layer body regions, C1 pedestals if needed, and local interconnect lines and then etched. The P2 layer etching is continued until the dielectric oxide is exposed over P1 areas uncovered by P2 (source, drain, P1 resistors). The source & drain P1 regions orthogonal to P2 gate regions are now self aligned to P2 gate edges. The S/D P2 regions may contact P1 via buried contacts. NMOS devices are blanket implanted with LDN N− dopant. Then PMOS devices are mask selected and implanted with LDP P− dopant as shown in FIG. 9.4. The implant energy ensures full dopant penetration through the residual oxide into the S/D regions adjacent to P2 layers.

A spacer oxide is deposited over the LDD implanted P2 using LTO or PECVD techniques. The oxide is etched to form spacers. The spacer etch leaves a residual oxide over P1 in a first embodiment, and completely removes oxide over exposed P1 in a second embodiment. The latter allows for P1 salicidation at a subsequent step. Then NMOS devices & N+ poly interconnects are blanket implanted with N+. The implant energy ensures full or partial dopant penetration into the 80A residual oxide in the S/D regions adjacent to P2 layers. This doping gets to gate, drain & source of all NMOS devices and N+ interconnects. The P+ mask is used to select PMOS devices and P+ interconnect, and implanted with P+ dopant as shown in FIG. 9.5. PMOS gate, drain & source regions receive the P+ dopant. This N+/P+ implants can be done with N+ mask followed by P+ mask. The V_{T} implanted P1 regions are now completely covered by P2 layer and spacer regions, and form channel regions of NMOS & PMOS transistors.

After the P+/N+ implants, Nickel is deposited over P2 and salicided to form a low resistive refractory metal on exposed poly by RTA. Un-reacted Ni is etched as shown in FIG. 9.6. This 80A-500A thick Co-salicide (or Ni, or any other metal salicide) connects the opposite doped poly-2 regions together providing low resistive poly wires for data. In one embodiment, the residual gate dielectric left after the spacer prevents P1 layer salicidation. In a second embodiment, as the residual oxide is removed over exposed P1 after spacer etch, P1 is salicided. The thickness of Ni deposition may be used to control full or partial salicidation of P1 regions. Fully salicided S/D regions up to spacer edge facilitate high drive current due to lower source and drain resistances.

An LTO film is deposited over P2 layer, and polished flat with CMP. A second contact mask C2 is used to open contacts into the TFT P2 and P1 regions in addition to all other contacts to substrate transistors. In the shown embodiment, C1 contacts connecting latch outputs to substrate transistor gates require no C2 contacts. Contact plugs are filled with tungsten, CMP polished, and connected by metal as done in standard contact metallization of IC's as shown in FIG. 9.7.

A TFT process sequence similar to that shown in FIG. 9 can be used to build complementary Gated-FET thin film devices. Compared with CMOS devices, these are bulk conducting devices and work on the principles of JFETs. A full disclosure of these devices are provided in application Ser. No. 8/413,808 entitled “Insulated-Gate Field-Effect Thin Film Transistors”, filed on Apr. 14, 2003 and list as inventor Mr. R. U. Madurawe, the contents of which are incorporated herein by reference. The process steps facilitate the device doping differences between MOSFET and Gated-FET devices, and simultaneous formation of complementary Gated-FET TFT devices. A detailed description for this process was provided when describing FIG. 9 earlier and is not repeated. An exemplary CGated-FET process sequence may use one or more of the following steps:

C1 mask & etch

W-Silicide plug fill & CMP

˜200A poly P1 (amorphous poly-1) deposition

P1 mask & etch

Blanket or masked Vtn N− implant (Gated-NFET V_{T})

Vtp mask & P− implant (Gated-PFET V_{T})

TFT Gox (70A-200A PECVD) deposition 200A P2 (amorphous poly-2) deposition

Blanket or masked P+ implant (Gated-NFET gate & interconnect)

N+ mask & implant (Gated-PFET gate & interconnect)

P2 mask & etch

Blanket or masked LDN Gated-NFET N tip implant

LDP mask and Gated-PFET P tip implant

Spacer LTO deposition

Spacer LTO etch to form spacers & expose P1

Ni deposition

RTA salicidation and poly re-crystallization (exposed P1 and P2)

Fully salicidation of exposed P1 S/D regions

Dopant activation anneal

Excess Ni etch

ILD oxide deposition & CMP

C2 mask & etch

W plug formation & CMP

M1 deposition and back end metallization

As the discussions demonstrate, memory controlled pass transistor logic elements provide a powerful tool to make switches. The ensuing high cost of memory can be drastically reduced by the 3-dimensional integration of configuration elements and the replaceable modularity concept for said memory. When the area is smaller, the wire lengths are shorter and power required to switch wire loads is less. These advances allow much lower power consumption in 3D FPGA designs. In one aspect, a cheaper memory element allows use of more memory for programmability. That enhances the ability to build large logic blocks (i.e. course-grain advantage) while maintaining smaller element logic fitting (i.e. fine-grain advantage). Furthermore larger grains need less connectivity: neighboring cells and far-away cells. That further simplifies the interconnect structure and power to switch interconnects. Additional methods to reduced power such as power up circuits and power up sequences are discussed next.

The semiconductor device of FIG. 10 comprises programmable logic circuits 1051 that can be grouped together into a first block 1050. These circuits may be positioned in a first module layer such as 850 in FIG. 8 in a 3D IC, or these may be grouped to form a first set of circuits from a plurality of circuits in a 2D IC. The plurality of logic circuits 1051 is powered by a first power supply voltage 1030, and a ground supply voltage 1040. Without the appropriate voltage levels, especially without power 1030, circuits 1051 are non functional. The FIG. 10 device comprises a configuration circuit 1054 that has a plurality of memory elements 1055. The configuration circuit elements can be combined into a second circuit block 1054. The circuit 1054 may be positioned in a second module layer such as 852 in FIG. 8 in a 3D IC, or these may be grouped to form a second set of circuits from a plurality of circuits in a 2D IC. Each memory element 1055 generates a memory signal 1070. The configuration circuit 1054 is powered by second power supply voltage 1010, and a ground supply voltage 1040. It is possible to change the ground voltage such that the shown 1040 ground voltages are not shorted together. Without the appropriate voltage levels, especially power 1010, the circuit 1054 is non functional. In addition, without valid data in memory elements 1055, the memory signals 1070 are meaningless. Each of the memory signals 1070 is coupled to a voltage conversion logic circuit 1053, which is powered by a third power supply voltage 1020 and a ground supply voltage 1040. Each voltage conversion circuit 1053 receives a memory signal 1070 from a memory element 1055 and generates a control signal 1060 that is coupled to a logic circuit 1051 to program the logic circuit. A memory data state determines a binary signal level. Without meaningful data in the memory elements, the logic circuit remains undefined, and could enter a damaging “contention” condition for the semiconductor device. It can consume high power. The conversion circuits 1053 can be grouped into circuit block 1052. Circuit block 1052 may be positioned in the second module layer such as 852 in FIG. 8 in a 3D IC. Circuit block 1052 may be positioned in the first module layer such as 850 in FIG. 8 in a 3D IC, or in a third separate module layer in between 1050 and 1054. Circuit block 1052 may be grouped to form a third set of circuits from a plurality of circuits in a 2D IC. However, as circuit 1052 is powered by a third power supply voltage 1020, keeping that voltage level at ground level allows all control signals to be at zero (ground) level regardless of valid or invalid data in the memory elements 1055 of configuration circuit 1054. To power up the device shown in FIG. 10, first, voltage 1010 is slowly ramped from ground to the desired voltage level (0.7 to 12V range, preferably 3.3V). Circuits that are required to distribute the voltage level 1010 to configuration circuit 1054 are all powered by said 1010 voltage. During this time, voltages 1030 and 1020 are held at ground causing no power surges and contentious conditions within the IC. When the voltage has reached the desired level, the memory elements are ready to receive valid data. Such memory data can be received (if the circuits operate by supply 1010) to configure the device. In a preferred embodiment, the memory data is received by logic circuits in 1040. Thus, after 1010 has reached voltage stability, power supply 1030 is slowly ramped up to the desired level (0.7 to 5V range, preferably 1.2V). During this time even if the memory data is at invalid state, the supply 1020 held at ground level delivers zero states on all the control signals to prevent logic circuit damage. Once voltage 1030 is stabilized, memory data is read from an external Boot ROM and written into internal memory locations 1055 within configuration circuit 1054. The memory is now set for a valid operating condition for programmable logic circuits. Then the third power supply 1020 is ramped to the desired value (0.7 to 12V range, preferably 2.5V). In a preferred embodiment, voltage 1010 is selected to be in 1 to 10 volt range, typically 3.3 volts; voltage 1020 is selected in the 0.7 to 3.3 volt range, typically 2.5 volts; and voltage 1030 is selected in the 0.5 to 2.5 volt range, typically 1.2 volts. These voltages are in the zero to 10 volt range, and as process geometries shrink, the voltages also reduce in magnitude. It should be noted that power voltages 1020 and 1010 may be internally generated from a single power supply 1030 to follow the same power up sequence without deviating from the scope of this work.

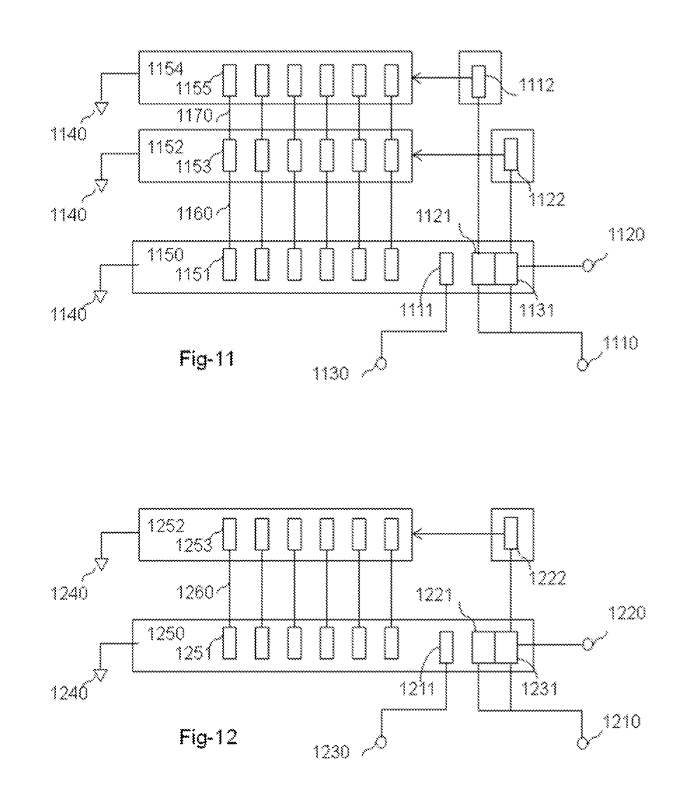

FIG. 11 shows an IC that is fabricated in 3-dimensional manner, wherein all the power supplies interface with base logic layer. Base layer 1150 comprises logic circuits 1151 and 1111 adapted to handle power supply voltage 1110, and circuits 1121 and 1131 adapted to handle power supply voltages 1120 and 1130. Typically, supply 1130 is in the range of 0.7 to 5.0 volts, preferably in the range of 1 to 1.8 volts, and more preferably 1.2 volts. Supply 1110 may be in the range of 0.7 volts to 12 volts, preferably in the range of 1.8 to 5 volts, and more preferably 3.3 volts. Supply 1120 may be in the range of 0.7 to 10 volts, preferably in the range 1 to 3.3 volts, and more preferably 2.5 volts. First, voltage 1110 is ramped. Circuit 1121 is activated to power up configuration circuit 1154. Circuit 1121 delivers power voltage to circuit 1112 which distributes power 1110 to each memory element 1155 located in configuration circuit 1154. Voltage 1110 powers up circuit 1131, which enables voltage 1120 to couple to circuit 1122 that distributes voltage 1120 to each of the voltage conversion circuit 1153 in the portion 1152 of configuration circuit. When voltage 1120 is held at ground level, same ground level as voltage 1140, each conversion circuits 1153 in the voltage conversion circuit block 1152 generates a control signal at ground voltage level. Thus all control signals 1160 configuring the PLD are at ground voltage ensuring low power consumption and safe operating conditions for the PLD. When supply 1110 is fully ramped up, volatile memory elements in 1154 attain random data states. If the memory elements are non-volatile, they would power up to a valid state. However, if there is no existing configuration or the existing configuration needs to be changed to a new configuration, during the transition, there are no correct memory signal states even for non-volatile memory elements. Second, logic supply 1130 is powered up, enabling all logic circuits and the memory interface circuits to power up. External Boot ROM memory data is then received by logic circuits such as 1111 and directed to circuits 1121 and 1112 to load the configuration data to memory elements 1155. The logic circuit blocks further manage all chip control functions such as requesting data. When the configuration circuit 1154 is fully configured, a configuration complete signal is generated. During configuration, the logic circuits 1151 are kept in a quiescent state by the ground voltage state of the control signals 1160. Once the chip is fully configured, the conversion block power voltage 1120 is ramped to desired level. Voltage 1120 is supplied to voltage conversion circuits 1153, and each control signal reaches either the ground voltage level or the 1120 supply voltage level based on the proper memory element data state and memory signal 1170. The FPGA/PLD is fully configured for proper functionality. The FPGA shown in FIG. 10 and FIG. 11 are reprogrammable. For every valid memory pattern loaded to configuration circuit, a different functionality logic device is obtained.

The programmable logic device of FIG. 11 comprises: a first power supply 1130 coupled to a first plurality of logic circuits 1150 including a programmable logic circuit 1151; and a second power supply 1110 coupled to a second logic circuit 1121/1131 and a configuration circuit 1154, the configuration circuit 1154 comprising a plurality of memory elements 1155, each memory element 1155 generating a memory signal 1170, the memory signal 1170 coupled to a voltage conversion circuit 1153, the voltage conversion circuit 1153 generating a control signal 1160; and a third power supply 1120 coupled to the second logic circuit 1121/1131 and each of the conversion circuits 1153; and a ground voltage 1140 coupled to all of the said circuits (1150, 1152, 1154 etc.); and a method to power up the power supply voltages starting with all supply voltages at the ground level, the method comprised of: ramping up the second power supply 1110 to power up the second logic circuit 1121/1131 and the configuration circuit 1154, and to distribute the third supply 1120 voltage to the voltage conversion circuits 1152; and ramping up the first power supply 1130 to power up the first plurality of logic circuits 1150 and load valid memory data to the configuration circuit 1154 from an external memory source; wherein, while the third power supply 1120 is at ground voltage level, each said control signal 1160 is at ground voltage level regardless of memory data 1155 in the configuration circuit 1154.

In a first embodiment of FIG. 11, all circuits shown in circuit block 1150, including configuration memory loading decoders and drivers, are constructed on a silicon substrate using high mobility CMOS transistors. The configuration circuit 1154 and the conversion circuit 1152 are constructed in a thin-film-transistor (TFT) layer. The TFT layer is positioned above or below the substrate layer. The thin film layers may be laser crystallized to improve mobility. FIG. 11 allows a vertical coupling scheme for control signals 1160 to couple to programmable logic 1151. The area of 3D IC is much smaller than a 2D IC. The configuration circuit 1154 including the conversion circuit 1152 is physically separated from the logic circuits 1150, each located in a “module layer” as previously defined. This lends to easy conversion of the FPGA in FIG. 11 to an ASIC with better reliability and lower cost.

FPGA to ASIC conversion is described next. In FIG. 3B FPGA, control signal S₀ is either at logic zero (ground) or logic one (power) voltage levels. The exact voltage levels can be duplicated by generating S₀ with a metal wire coupled to ground or power supply respectively. Thus every control signal can be duplicated by a metal pattern to duplicate the signal levels. In FIG. 6B, control signal S₀ is either at voltage V_{S} level or V_{D} level, the exact value based on the memory state stored in the latch 613/614. Same exact voltage levels can be duplicated by a metal wire coupled to V_{S} supply or V_{D} supply, in which case the latch is no longer required. Thus the FPGA of FIGS. 10 & 11 can be converted to an ASIC by simply replacing the voltage conversion circuit 1052/1152 with a metal pattern, wherein each control signal is either coupled to V_{S} or V_{D}. When V_{D} is held at ground voltage level, every control signal is forced to ground in the ASIC.

Such an ASIC derived from the FPGA in FIG. 11 is shown in FIG. 12. The configuration circuit 1154 & 1152 of FIG. 11 is completely replaced by hard-wired metal pattern 1252. An alternative description is that memory elements & memory access circuitry in 1154 of FIG. 11 are completely removed, and voltage conversion circuit 1152 is replaced by a simple metal pattern to achieve the same result. Each new conversion circuit 1254 in FIG. 12 comprises a metal link either coupled to power supply 1220 to generate a first logic control state, or coupled to ground supply 1240 to generate a second logic control state. It is easily noted that when voltage source 1220 is held at ground, each control signal 1260 is also at ground voltage. Logic circuits in block 1250 (including interconnects that couple logic) are identical with circuits in block 1150 of FIG. 11—thus the functionality and timing of the two ICs remain identical. No external memory is needed to program the ASIC of FIG. 12 as all the memory data is hard wired (saving the cost of the Boot ROM in the system). When voltage level 1220 is held at ground during power up, even in the ASIC version, all inputs to buffers go to a defined input state through the conducting PMOS device (such as 701 shown in FIG. 7A) during power up. In typical ASICs this is not the case; rather the inputs can be undefined until some trip point voltage is reached within circuits leading up to the buffer input. Therefore, the presented scheme provides a better power management during ramp-up period of ASIC devices as well.

Although an illustrative embodiment of the present invention, and various modifications thereof, have been described in detail herein with reference to the accompanying drawings, it is to be understood that the invention is not limited to this precise embodiment and the described modifications, and that various changes and further modifications may be effected therein by one skilled in the art without departing from the scope or spirit of the invention as defined in the appended claims.

What is claimed is:

1. A multiplexer (MUX) for a programmable logic device comprising:
a plurality of inputs and an output; and
a configuration circuit comprising a plurality of memory elements, each memory element generating a control signal, the configuration circuit comprising a first mode of operation to force each of said control signals to a first voltage level regardless of the memory state in the memory element; and
a first device coupling a power supply voltage to the output, said first device having a gate electrode controlled by a said control signal of the configuration circuit; and
one or more second devices coupling one or more said inputs to the output, each said second device having a gate electrode controlled by a said control signal of the configuration circuit;
wherein, the first device is in a conducting state to couple the power supply voltage to the MUX output during the first mode of operation of the configuration circuit.

2. The device of claim 1, wherein each of said one or more second devices is in a non-conducting state to decouple the inputs from the output during the first mode of operation of the configuration circuit.

3. The device of claim 1, wherein the configuration device is coupled to a first power supply voltage and a second power supply voltage.

4. The device of claim 1, wherein said first device is a PMOS transistor and a said second devices is an NMOS transistor.

5. The device of claim 1, wherein the memory element comprises a volatile memory element.

6. The device of claim 1, wherein the configuration circuit comprises a plurality of voltage conversion circuits, each conversion circuit coupled to a said memory element to read a memory signal and generate a said control signal.

7. The device of claim 6, wherein each said memory elements is coupled to a first power voltage, and the voltage conversion circuit is coupled to a second power voltage, and wherein during the first mode of operation the second power voltage level is held at ground voltage level until the first power voltage is ramped up and the memory elements are configured.

8. The device of claim 1, wherein the memory element comprises one of: a fuse link, an anti-fuse capacitor, an SRAM cell, a DRAM cell, a metal optional link, an EPROM cell, an EEPROM cell, a flash cell, a ferro-electric element, an electro-chemical cell, an electro-magnetic cell, a carbon nano-tube, an optical element and a magnetic memory element.

9. A buffer circuit of a programmable logic device, the circuit comprising:
a buffer having a plurality of inverters coupled in series, the first inverter in the series having a buffer input; and
a programmable multiplexer (MUX) comprising:
a plurality of MUX inputs and a MUX output coupled to the buffer input; and
a configuration circuit comprising a plurality of memory elements, each memory element generating a control signal, the configuration circuit having a mode wherein each of said control signals is forced to a first voltage level regardless of the memory state in the memory element; and
a first MUX device coupling a power supply voltage to the MUX output, said first MUX device having a gate electrode controlled by a said control signal of the configuration circuit; and
one or more second MUX devices coupling one or more MUX inputs to the MUX output, each said second MUX device having a gate electrode controlled by a said control signal of the configuration circuit;
wherein, the first MUX device is in a conducting state to couple the power supply voltage to the buffer input during a time interval needed for power up and configuration of memory elements in the configuration circuit.

10. The device of claim 9, wherein each of said one or more second MUX devices is in a non-conducting state to decouple the MUX inputs from the buffer input during the time interval needed for power up and configuration of memory elements in the configuration circuit.

11. The device of claim 9, wherein the configuration device is coupled to a first power supply voltage and a second power supply voltage.

12. The device of claim 9, wherein said first MUX device is a PMOS transistor and a said second MUX device is an NMOS transistor.

13. The device of claim 9, wherein the memory element comprises a volatile memory element.

14. The device of claim 9, wherein the configuration circuit comprises a plurality of voltage conversion circuits, each voltage conversion circuit coupled to a said memory element to read a memory signal and generate a said control signal.

15. The device of claim 14, wherein each said memory elements is coupled to a first power voltage, and the voltage conversion circuit is coupled to a second power voltage, and wherein the second power voltage level is held at ground to force all of said control signals to ground voltage level.

16. The device of claim 9, wherein the memory element comprises one of: a fuse link, an anti-fuse capacitor, an SRAM cell, a DRAM cell, a metal optional link, an EPROM cell, an EEPROM cell, a flash cell, a ferro-electric element, an electro-chemical cell, an electro-magnetic cell, a carbon nano-tube, an optical element and a magnetic memory element.

17. A programmable logic device comprising:
a configuration circuit having:
a plurality of memory elements, each memory element generating a control signal; and
a first mode of operation to force all said control signals to ground voltage level; and
a programmable logic circuit comprising a plurality of programmable elements and a plurality of programmable interconnects, each said programmable element and interconnect coupled to one or more of said control signals; and
a programmable buffer having an input coupled by a PMOS pass-gate to a power supply voltage, the gate electrode of said PMOS pass-gate coupled to a said control signal;
wherein, the configuration circuit is held in said first mode during a time interval to power up and configure the programmable logic device.

18. The device of claim 14, wherein the configuration circuit comprises a plurality of voltage conversion circuits, each conversion circuit coupled to a said memory element to read a memory output and generate a said control signal.

19. The device of claim 14, wherein the memory element comprises one of: a fuse link, an anti-fuse capacitor, an SRAM cell, a DRAM cell, a metal optional link, an EPROM cell, an EEPROM cell, a flash cell, a ferro-electric element, an electro-chemical cell, an electro-magnetic cell, a carbon nano-tube, an optical element and a magnetic memory element.

20. The device of claim 14, wherein the programmable logic device comprises one or more of: look-up table logic elements, memory blocks, intellectual property cores, programmable routing elements, input/output pads, product terms, clock buffers, analog cores, registers and digital signal processing units.

21. A programmable logic device comprising:
a first power supply coupled to a first plurality of logic circuits including a programmable logic circuit; and
a second power supply coupled to a second logic circuit and a configuration circuit, the configuration circuit comprising a plurality of memory elements, each memory element generating a memory signal, the memory signal coupled to a voltage conversion circuit, the voltage conversion circuit generating a control signal; and
a third power supply coupled to the second logic circuit and each of the conversion circuits; and
a ground voltage coupled to all of the said circuits; and
a method to power up the power supply voltages starting with all supply voltages at the ground voltage level, the method comprised of:
ramping up the second power supply to power up the second logic circuit and the configuration circuit, and to distribute the third supply voltage to the voltage conversion circuits; and
ramping up the first power supply to power up the first plurality of logic circuits and load valid memory data to the configuration circuit from an external memory source;
wherein, while the third power supply is at ground voltage level, each of said control signals is at ground voltage level regardless of the memory data in the configuration circuit.

22. The device of claim 21, wherein the power up method further comprises:
ramping up the third power supply to power up each said voltage conversion circuits, whereby each of the control signals is driven to either the third power voltage level or the ground voltage level based on the memory signal.
